(19) United States
(12) Patent Application Publication
(10) Pub. No.: US 2008/0131979 A1
(43) Pub. Date: Jun. 5, 2008

(54) Vapor-Phase Growth System and Vapor-Phase Growth Method

(75) Inventor: Eiryo Takasuka, Itami-shi (JP)

Correspondence Address: Judge Patent Associates, Dojima Building, 5th Floor, 6-8 Nishitemma 2-Chome, Kita-ku, Osaka-Shi, 530-0047, omitted

(73) Assignee: SUMITOMO ELECTRIC INDUSTRIES, LTD., Osaka-shi (JP)

(21) Appl. No.: 11/949,051

(22) Filed: Dec. 3, 2007

(30) Foreign Application Priority Data
Dec. 4, 2006 (JP) JP-2006-327176
Feb. 20, 2007 (JP) JP-2007-039342

(51) Int. Cl. C23C 16/34; H01L 21/66

(52) U.S. Cl. 438/14; 118/728; 118/712; 257/E21.529

(57) ABSTRACT

Affords a vapor-phase growth system and vapor-phase growth method that enable gas leakage reduction. A vapor-phase growth system (1) is provided with a flow channel (4), a flow channel (5) linked to the downstream end of the flow channel (4), and susceptor (17) for supporting a substrate 21 so that the top surface of the substrate (21) is exposed in the interior space 11. A flow path (7) is formed by clearance between the outer peripheral surface (4a) of the flow channel 4 and the inner peripheral surface (5a) of the flow channel 5, leading from the interior region (11) to a hollow interior portion (8) in a reaction chamber (9), and a width W of the flow path (7) is from more than 3 mm to 10 mm or less.

### BACKGROUND OF THE INVENTION

1. Technical Field

The present invention relates to vapor-phase growth systems and vapor-phase growth methods; more specifically, the invention relates to vapor-phase growth systems and vapor-phase growth methods employed in the deposition of Group III-V nitride semiconductor films.

2. Description of the Related Art

Gallium nitride (GaN), gallium arsenide (GaAs), indium phosphide (InP), and other compound semiconductors are ideally suited to such photonic and electronic applications as light-emitting elements and high-speed electronic devices. Crystals of these semiconductor compounds are generally grown on substrates by metalorganic chemical vapor deposition (MOCVD) and hydride vapor-phase epitaxy (HVPE). Particularly with MOCVD techniques, multilayer film stacks having such microstructures as multiple-quantum wells (MQWs) can be formed with satisfactory controllability.

For vapor-phase growth systems tailored to carrying out MOCVD, a variety of structures have been proposed in order to improve the uniformity of the grown films. Japanese Unexamined Pat. App. Pub. No. H05-190465, for example, discloses a configuration in which a rotatable susceptor for carrying a substrate is provided in a reactor, and a flow channel is provided within the reactor in the space between the gas supply port and the susceptor. With this patent reference, the provision of the flow channel brings the gas flow to a near laminar-flow state. Japanese Unexamined Pat. App. Pub. No. H06-216030, meanwhile, discloses a configuration in which a flow channel is provided within the reactor in the entire space from the gas supply port to the exhaust port. Further, Japanese Unexamined Pat. App. Pub. Nos. 2000-100726 and 2006-66605 disclose configurations in which an intermediate flow channel is provided directly above the susceptor, and a downstream flow channel is provided in a location near the exhaust port, and in a position where the intermediate and downstream flow channels are connected, a gas flow path leading outside the flow channels is formed by a clearance between the outer peripheral surface of the intermediate flow channel and the inner peripheral surface of the downstream flow channel.

A problem with the vapor-phase growth systems described above, however, has been that source gases leak from the flow-channel interior. That is, the susceptor being designed to be rotatable with respect to the flow channel leaves the flow channel not hermetically sealed, such that a gap inevitably is present between the susceptor and the flow channel. Consequently, when source gas flows into the flow channel during film deposition, raising the channel interior pressure, through the gap the source gas leaks outside from the flow channel. The leaking of the source gas outside the flow channel disturbs the flow of source gas inside the flow channel, adversely affecting the thickness uniformity of the grown films, and leading to the unwanted buildup of film material in the vicinity of the gap.

To address this gas flow issue, Japanese Unexamined Pat. App. Pub. No. 2000-66605 teaches making the clearance between the outer peripheral surface of the intermediate flow channel and the inner peripheral surface of the downstream flow channel from 0.01 mm to 3 mm. Nevertheless, designing the gas flow path clearance to be 3 mm or less would make for poor reproducibility, due to leakage through the clearance, especially when quartz is used for the material of the flow channel. A further problem that may happen is when the pressure outside the flow channel becomes higher than that inside the flow channel and, in reverse, gas flows into the flow channel from outside the flow channel, contaminating the grown films or otherwise disturbing the film uniformity.

### BRIEF SUMMARY OF THE INVENTION

Accordingly, an object of the present invention is to make available vapor-phase growth systems and vapor-phase growth methods that make it possible to keep gas leakage under control.

One aspect of the present invention is a vapor-phase growth system provided with: a first gas supply duct; a second gas supply duct linked to the downstream end of the first gas supply duct; and a substrate support pedestal for supporting a substrate so that one of the substrate principal faces is exposed to the interior of the first gas supply duct. A flow path is constituted by a clearance between the outer peripheral surface of the first gas supply duct and the inner peripheral surface of the second gas supply duct, the flow path leading from the inside to the outside of the first gas supply duct, and the flow path width being from greater than 3 mm to 10 mm or less.

With the vapor-phase growth system in one aspect of the present invention, even in the situation in which pressure inside the first gas supply duct has gone higher than that outside the first gas supply duct, the flow path formed by the clearance between the outer peripheral surface of the first gas supply duct and the inner peripheral surface of the second gas supply duct decreases the pressure gradient between the inside and the outside of the first gas supply duct. As a result, gas leakage from the first gas supply duct can be kept to a minimum. In particular, rendering the flow path width 10 mm or less produces fluid resistance in the flow path sufficient to enable keeping gas leakage effectively under control. Meanwhile, rendering the flow path width greater than 3 mm improves the flow path dimensional precision.

The present invention in another aspect is a vapor-phase growth system provided with: a first gas supply duct; a second gas supply duct linked to the downstream end of the first gas supply duct; and a substrate support pedestal for supporting a substrate so that one of the substrate principal faces is exposed to the interior of the first gas supply duct. A flow path is constituted by the clearance between the outer peripheral surface of the first gas supply duct and the inner peripheral surface of the second gas supply duct, the flow path leading from the inside to the outside of the first gas supply duct, and the ratio A/L of the area A mm² of the flow path cross-sectional area to the length L mm of the flow path being between 0.9 mm and 20 mm inclusive.

With the vapor-phase growth system in another aspect of the present invention, even in the situation in which pressure inside the first gas supply duct has gone higher than that outside the first gas supply duct, the flow path formed by the clearance between the outer peripheral surface of the first gas supply duct and the inner peripheral surface of the second gas supply duct decreases the pressure gradient between the inside and the outside of the first gas supply duct. As a result, gas leakage from the first gas supply duct can be kept to a minimum. In particular, rendering the ratio A/L 0.9 mm or more enables stabilization of the gas flow in the second gas supply duct, preventing fluctuations of pressure and flow rate in the first gas supply duct. Furthermore, rendering the ratio A/L 20 mm or less produces resistance in the flow path sufficient to enable keeping gas leakage effectively under control.

It should be understood that in the present description, “flow-path cross-sectional area” means the area of a cross section perpendicular to the direction of the gas flow in the flow path.

It is preferable that the vapor-phase growth system of the present invention is further provided with a chamber for housing the first and second gas supply ducts, substrate support pedestal, and flow path. The chamber has a supply port for supplying gas to that portion of the chamber interior which is exterior to the first gas supply duct.

In such a vapor-phase growth system, even in the situation in which pressure inside the first gas supply duct has gone higher than that outside the first gas supply duct, difference in pressure between the inside and the outside of the first gas supply duct can be decreased by supplying gas from the supply port to increase the pressure outside the first gas supply duct. As a result, gas leakage from the first gas supply duct interior can be kept under control.

It is preferable that the vapor-phase growth system of the present invention is further provided with a differential-pressure meter for measuring pressure difference between the inside and outside of the first gas supply duct.

Because providing the vapor-phase growth system with the differential-pressure meter makes it possible to adjust, with reference to pressure difference between the inside and the outside of the first gas supply duct, the amount of gas supplied from the supply port, pressure in that portion of the chamber interior which is exterior to the first gas supply duct can be always adjusted so as to be the proper pressure. This makes it possible to keep gas leakage under control.

A further aspect of the present invention is a vapor-phase growth method in which to carry out film deposition, gas is supplied over a substrate via a gas supply duct provided within a chamber; the method being furnished with: a step of measuring the pressure difference between the gas supply duct and the interior portion of the chamber interior which is exterior to the gas supply duct; and a step of supplying gas to that portion of the chamber which is exterior to the gas supply duct so that the pressure difference measured in the measuring step is made smaller.

With the vapor-phase growth method of the present invention, the pressure in that portion of the chamber interior which is exterior to the gas supply duct can be always adjusted so as to be proper pressure by adjusting, based on the difference in pressure between the inside and the outside of the gas supply duct, the amount of gas supplied to the outside of the supply line.

According to the vapor-phase growth system and vapor-phase growth method of the present invention, gas leakage can be kept under control.

From the following detailed description in conjunction with the accompanying drawings, the foregoing and other objects, features, aspects and advantages of the present invention will become readily apparent to those skilled in the art.

### BRIEF DESCRIPTION OF THE SEVERAL VIEWS OF THE DRAWINGS

FIG. 1 is a cross-sectional diagram illustrating the configuration of a vapor-phase growth system in Embodiment 1 of the present invention;

FIG. 2 is a cross-sectional diagram illustrating the configuration of a vapor-phase growth system in Embodiment 2 of the present invention;

FIG. 3 is a fragmentary cross-sectional diagram illustrating the configuration of a feature of a vapor-phase growth system in Embodiment 3 of the present invention, and is an enlarged diagram of the vicinity of the flue 7 in the vapor-phase growth system of FIG. 1; and

FIG. 4 is a cross-sectional diagram taken along the line IV-IV in FIG. 3, seen in the direction of the arrows.

### DETAILED DESCRIPTION OF THE INVENTION

Below, referring to the figures, a description will be made of embodiments according to the present invention.

### Embodiment 1

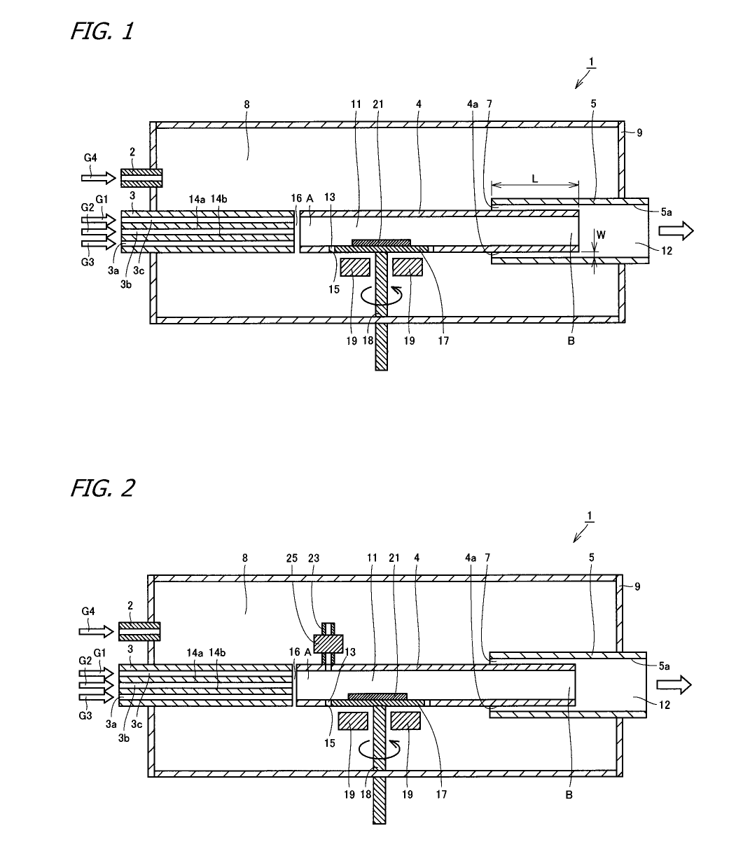

FIG. 1 is a cross-sectional view showing a construction of a vapor-phase growth system in Embodiment 1 of the present invention. Referring to FIG. 1, a vapor-phase growth system 1 in this embodiment is provided with: a flow channel 3; a flow channel 4 serving as the first gas supply duct; a flow channel 5 serving as the second gas supply duct; a reaction chamber 9; a susceptor 17 serving as the substrate support pedestal; and a heater 19. The reaction chamber 9 has a supply port 2 in the upper part of the left end of the reaction chamber 9 in FIG. 1. The flow channels 3, 4 and 5, respectively, susceptor 17, and heater 19 are housed in the reaction chamber 9. Each of the flow channels 3, 4 and 5, respectively is rectangular in cross-section when taken in a plane perpendicular to the drawing sheet.

The flow channel 3 is anchored to the lower part of the left end of the reaction chamber 9 in FIG. 1. The flow channel 3 is, for example, partitioned vertically by dividers 14a and 14b into three supply ports 3a, 3b and 3c, respectively.

The flow channel 4 is linked, spaced apart by a gap 16, to the downstream end of the flow channel 3 (right end in FIG. 1). A cut 15 is provided in the underside of the flow channel 4, and the susceptor 17, circularly planar in form, is arranged in the cut 15. A substrate 21 is carried on the susceptor 17, and the top surface of the substrate 21 is exposed to the interior space of the flow channel 4. The susceptor 17 is supported by a support post 18 and, rotated by a not-illustrated rotation mechanism, is rendered rotatable centered on the support post 18. A spiral heater 19 for heating the susceptor 17 is provided around the support post 18.

The flow channel 5 is linked to the downstream end of the flow channel 4. Flow channel 5 is greater than the flow channel 4 in height (vertical height in FIG. 1), and in width (length perpendicular to plane of the figure), and the downstream end of the flow channel 4 is inserted into the upstream end of the flow channel 5. As a result, a flow path 7 is constituted by clearance between the outer peripheral surface 4a of the flow channel 4 and the inner peripheral surface 5a of the flow channel 5. The flow path 7 leads from the interior space 11 of the flow channel 4 and a cavity 12 within the flow channel 5 to a hollow interior portion 8 within the reaction chamber 9. Herein, the hollow interior portion 8 is the portion of the interior of the reaction chamber 9 that is exterior to the flow channels 3, 4 and 5. The width W of the flow path 7 is greater than 3 mm and less than 10 mm, and the length L of the flow path 7 is 50 mm or more.

In the vapor-phase growth system 1, deposition is carried out in the following manner. The substrate 21 is placed on the carrying surface of the susceptor 17, and the susceptor 17 is heated to a temperature level of 1100° C. by the heater 19. Next, gases G1, G2 and G3 are supplied over the substrate 21 via the flow channels 3 and 4 that are gas supply ducts, and deposition is performed. Specifically, with the heated susceptor 17 rotating, the gases G1, G2 and G3 are fed from the supply ports 3a, 3b and 3c, respectively. The gases G1, G2 and G3 flow through the flow channels 3, 4 and 5 to the right in the diagram.

In depositing III-V semiconductor layers including GaAs, InP, AlN, GaN, InN, AlGaN, InGaN, and AlInGaN, as the gas G1, purge gas such as H₂ (hydrogen) gas and N₂ (nitrogen) gas for controlling source gas reaction, is utilized. Furthermore, as the gas G2, trimethyl gallium (TMG), trimethyl indium (TMI), trimethylaluminum (TMA) and other metal-organic gases (source gases) containing Group III elements are utilized. In addition, as the gas G3, gas (source gas) containing a Group V element such as As, P, or N is utilized. Herein, the gases G2 and G3 may be diluted with H₂ gas, N₂ gas and/or Ar gas and/or other carrier gases in order to adjust gas flow. One specific example of what kinds of gases G2 and G3 is utilized is Trimethyl gallium (TMGa) diluted with H₂ (Ga (NH₃)₃) and ammonia (NH₃) diluted with H₂ respectively.

The gases G1, G2 and G3 are mixed in the interior space 11 of the flow channel 4, and as a result of the reaction between the gases G2 and G3, single crystal of compound semiconductor such as GaN is deposited on the top surface of the substrate 21. Gases after reaction is guided by the flow channel 5, and is discharged via the cavity 12 within the flow channel 5 to the outside of the reaction chamber 9.

Herein, shaping the flow channel 4, of which cross section is rectangular permits gas flow to get close to the substrate 21. Furthermore, introducing the gases G2 and G3, which are source gases, through the separate supply ports 3b and 3a means that the gases G2 and G3 can be supplied isolated from each other until the vicinity of the substrate 21, making it possible to keep the gases G2 and G3 from reacting—particularly in instances where they are highly reactive with each other—before they reach the substrate 21. Moreover, making the gas G1 flow in proximity to the inner surface, opposite from the substrate 21, of the flow channel 4 curbs the deposition of reactants in the vicinity of the inner surface of the flow channel 4.

Because the width W of the flow path 7 in the vapor-phase growth system 1 of this embodiment is greater than 3 mm, the flow path cross sectional area can be reproduced with a margin of dimensional error of 3.3% or less even if the width W is manufactured with a dimensional precision of 0.1 mm or worse. Since the size of the flow path 7 cross-sectional area has a considerable influence on the pressure gradient in the flow path 7, the dimensional precision of the width W is a crucial factor in reducing leakage of gas from inside to outside the flow channel 4. In the situation in which a flow channel 4 is newly fabricated at the dimensional precision described above and is replaced, the reproducibility of a pressure difference between either end of the flow path 7 will fall within 3.3% tolerance. Variation in film thickness uniformity with this tolerance was satisfactory in that it was not to the extent that would require post-flow-channel-replacement readjustments.

Furthermore, inasmuch as the width W of the flow path 7 is 10 mm or less, proper resistance in the flow path 7 reduces gas leakage from the inside of the flow channels 4 and 5. Moreover, bringing the length L of the flow path 7 to 50 mm or more can produce more sufficient resistance in the flow path 7. In the situation in which the length L is 100 mm, the total flow rate of gases G1, G2, and G3 is from 30 SLM to 100 SLM, gas pressure is within the range of 50 kPa to 101 kPa, and the flow path width is 3.1 mm, flow rate of the gas G4 required to sufficiently reduce gas leakage from an interval was from 20 SLM to 40 SLM. At the flow path width W of 10 mm, flow rate of 60 SLM to 140 SLM was required. At a flow path width of more than 10 mm, the flow rate required for the gas G4 increases further, which is disadvantageous from the perspective of manufacturing costs.

Meanwhile, feeding the gases G1, G2 and G3 through the flow channels 3, 4 and 5, respectively makes pressure inside the flow channels 3, 4 and 5 higher than the pressure outside them—in other words, the pressure in the flow channels 3, 4 and 5 is made higher than that in the hollow interior portion 8 within the reaction chamber 9. As a result, a slight amount of gases G1, G2 and G3 leaks via an interval 13 between the cut 15 and the susceptor 17, and via the flow path 7, to the hollow interior portion 8.

In the vapor-phase growth method in this embodiment of the present invention, thus, the gas G4 that is purge gas is supplied via the supply port 2 to the hollow interior portion 8 in order to reduce gas leakage from the flow channels 3, 4 and 5 to the hollow interior portion 8. Supplying the hollow interior portion 8 with the gas G4 lessens difference between the pressure in the flow channels 3, 4 and 5 and that in the hollow interior portion 8 to reduce the leakage of the gases G1, G2 and G3.

Furthermore, the amount of supply of the gas G4 is preferably adjusted in the following manner. Generally, feeding the gases G1, G2 and G3 through the flow channels 3, 4 and 5 creates pressure gradient in the interior space 11 of the flow channel 4, making the pressure at the upstream end A of the flow channel 4, PA, greater than the pressure at the downstream end B of the flow channel 4, PB. For example, in the situation in which an average flow velocity of the gases G1, G2 and G3 in the flow channel 4 is approximately 1 m/s, difference of about 10 Pa occurs between the pressure PA and the pressure PB. In the situation in which the pressure in the hollow interior portion 8, P8, within the reaction chamber 9 is lower than the pressure PB, the gases G1, G2 and G3 are prone to leak via the interval 13, and via the flow path 7, from the hollow interior portion 8 to the interior space 11. On the other hand, in the situation in which the pressure P8 is higher than the pressure PA, the gas G4 is prone to enter the interior space 11 via the interval 13 and the flow path 7, from the hollow interior portion 8 to the inter space 11. Therefore, if the amount of supply of the gas G4 at which the pressure P8 in the hollow interior portion 8 goes lower than the pressure PA and higher than the pressure PB is previously calculated, supplying such an amount of gas G4 keeps the gases G1, G2 and G3 from leaking, and keeps the gas G4 from entering the interior space 11, making it possible to make uniform flow of the gases G1, G2 and G3 in the interior space 11.

The vapor-phase growth system 1 in this embodiment is provided with the flow channel 4, flow channel 5 linked to the downstream end of the flow channel 4, and the susceptor 17 for carrying the substrate 21 so that the top surface of the substrate 21 is exposed in the interior space 11 of the flow channel 4. The flow path 7 is formed by clearance between the outer peripheral surface 4a of the flow channel 4 and the inner peripheral surface 5a of the flow channel 5, the flow path 7 leading from the interior space 11 to the hollow interior portion 8 within the reaction chamber 9, and a width W of the flow path 7 is more than 3 mm and to less than or equal to 10 mm.

With the vapor-phase growth system 1 in this embodiment, even in the situation in which the pressure in the interior space 11 of the flow channel 4 has gone higher than that in the hollow interior portion 8 within the reaction chamber 9, the flow path 7 makes the gradient of pressure between the interior space 11 and the hollow interior portion 8 smaller. As a result, leakage of the gases G1, G2 and G3 from the interior space 11 can be reduced. In particular, keeping the width W of the flow path 7 to 10 mm or less produces sufficient resistance in flow path, enabling effective reduction of the leakage of the gases G1, G2 and G3. Therefore, the flow of the source gas in the interior space 11 can be uniformed, and thus the uniformity of the deposited films can be improved. Furthermore, an extra film deposit in the proximity of the gap 16 on the flow channel 4 can be made less likely to occur. On the other hand, bringing the width W of the flow path 7 to more than 3 mm improves precision of the dimensions of the flow path 7.

The vapor-phase growth system 1 in this embodiment is additionally provided with the reaction chamber 9 for housing the flow channels 3, 4 and 5, respectively, susceptor 17, and flow path 7. The reaction chamber 9 has the supply port 2 for supplying the hollow interior portion 8 within the reaction chamber 9 with the gas G4.

Therefore, even in the situation in which pressure in the interior space 11 has gone higher than that in the hollow interior portion 8, the difference in pressure between the interior space 11 and the hollow interior portion 8 can be decreased by supplying with the gas G4 from the supply port 2 to increase the pressure in the hollow interior portion 8.

### Embodiment 2

FIG. 2 is a cross-sectional view showing a configuration of the vapor-phase growth system in Embodiment 2 of the present invention. Referring to FIG. 2, the vapor-phase growth system 1 in this embodiment differs from the vapor-phase growth system in Embodiment 1 in mounting of a differential-pressure meter 25. A capillary 23 leading to the hollow interior portion 8 within the reaction chamber 9 is provided on the top of the flow channel 4, and the differential-pressure meter 25 is mounted to the capillary 23. As to the position of the capillary 23, its preferable location is the middle between the upstream end, and the downstream end of the flow channel 4, or just above the center of the susceptor 17.

The differential-pressure meter 25 measures difference between the pressure in the interior space 11 of the flow channel 4 and that in the hollow interior portion 8 within the reaction chamber 9. The flow rate of the gas G4 to the hollow interior portion 8 is adjusted so that the pressure difference measured by the differential-pressure meter 25 decreases. The amount of the gas G4 to be supplied may be adjusted with a not-illustrated mass flow controller by sending a differential pressure signal to the mass flow controller. With the mass flow controller, the pressure in the hollow interior portion 8 can be suitably adjusted at all times, and the leakage of the gases G1, G2 and G3 can be effectively reduced.

### Embodiment 3

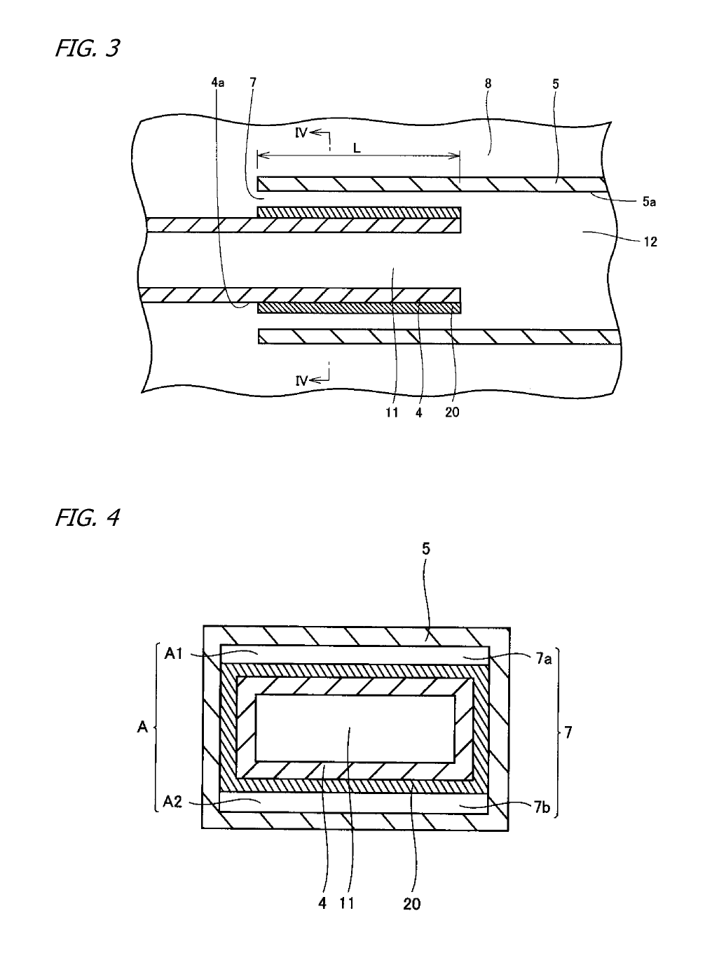

FIG. 3 is a cross sectional view showing a configuration of the vapor-phase growth system in Embodiment 3 of the present invention, and is an enlarged view around the flow path 7 in the vapor-phase growth system illustrated in FIG. 1. FIG. 4 is a cross-sectional view taken along the line IV-IV in FIG. 3, seen in the direction of the arrows.

Referring to FIGS. 3 and 4, a wall part 20 is arranged in between the rectangular—when viewed (as illustrated in FIG. 4) in a cross-section perpendicular to the flow path—flow channels 4 and 5. The wall part 20 is in contact with the outer peripheral surface of the flow channel 4 along the entire perimeter of the flow channel 4. The wall part 20 contacts also with the inner lateral sides of the flow channel 5. That is, the flow path 7 on either lateral side of the flow channel 4 is completely occupied by the wall part 20, and the flow path 7 is configured with the flue 7a on the top side of the flow channel 4, and with the flue 7b on the bottom side of the flow channel 4. As a result, the area A of a cross section through the flow path 7 is represented by the sum of the area A1 of a cross section through the flue 7a and the area A2 of a cross section through the flue 7b. It will be appreciated that the differential-pressure meter in Embodiment 2 may be mounted on the vapor-phase growth system 1 in this embodiment. It will likewise be appreciated that the flow path 7 may be formed by contacting the wall part 20 perimetrically along the inner surface of the flow channel 5, or may be formed by the shapes of the flow channels 4 and 5 themselves.

In this embodiment, the ratio A/L of the cross sectional area A mm² to the length L mm of the flow path 7 is between 0.9 mm and 20 mm inclusive. The area A mm² of the cross-section through the flow path 7 can be adjusted by the thickness of the wall part 20.

Herein, except for such a configuration, the vapor-phase growth system of this embodiment has the same configuration as that in Embodiment 1, so identical or equivalent features are labeled with identical reference marks, and their explanation will not be repeated.

According to the vapor-phase growth system in this embodiment, keeping the ratio A/L to 0.9 mm or more stables the flow of gas in the cavity 12 within the flow channel 5, making it possible to prevent the variations of the pressure and flow velocity in the interior space 11 of the flow channel 4. Moreover, keeping the ratio A/L to 20 mm or less allows the flow path 7 to produce sufficient flow path resistance, enabling the effective reduction of the gas leakage.

The inventor of the present invention confirmed the advantages of bringing the ratio A/L to 0.9 mm to 20 mm inclusive. Specifically, vapor-phase growth systems as illustrated in FIGS. 1, 3 and 4 were manufactured varying the ratio A/L. As to systems A1 to A9, the length L was made 110 (mm), and cross sectional area A was varied within the range of 10 to 1500 (mm²). As to systems B1 to B8, the cross sectional area A was made 200 (mm²), and the length L was varied within the range of 10 to 300 (mm). In each of these systems, the gases G1, G2 and G3 of the total amount of 64 SLM to 92 SLM were fed to carry out deposition. During the deposition, the hollow interior portion 8 was supplied with gas G4 (purge gas) via the supply port 2 so that gas leakage from the flow channels 3, 4 and 5 into the hollow interior portion 8 and the gas entrance from the hollow interior portion 8 into the flow channels 3, 4 and 5 were minimized, and a flow rate of this purge gas was measured. Additionally, the stability of pressure in the cavity 12 within the flow channel 5 was evaluated during the deposition. Tables I and II demonstrate the flow rate of the purge gas supplied to the hollow interior portion 8 and the pressure stability in the cavity 12 within the flow channel 5, in each of the systems. Here, systems in which the extent of fluctuation of the total pressure in the cavity 12 was 10% or more were judged “pressure-stability inferior,” while systems in which the extent was less than 10% were judged “pressure-stability superior.”

TABLE I

| | | | | Flow rate of purge | Pressure | |
|---|---|---|---|---|---|---|
| | | | | gas supplied to | stability | |
| | Cross-sectional | Length L | Ratio A/L | hollow interior 8 | in flow | |
| System | area A (mm²) | (mm) | (mm) | (SLM) | channel 5 | Remarks |
| System A1 | 10 | 110 | 0.09 | 1.2 | Inferior | Comparison |
| System A2 | 15 | | 0.14 | 1.8 | Inferior | examples |
| System A3 | 50 | | 0.45 | 6.0 | Inferior | |
| System A4 | 100 | | 0.91 | 11.9 | Superior | Present |
| System A5 | 300 | | 2.73 | 35.8 | Superior | invention |
| System A6 | 400 | | 3.64 | 47.7 | Superior | examples |
| System A7 | 500 | | 4.55 | 59.6 | Superior | |
| System A8 | 1000 | | 9.09 | 119.2 | Superior | |
| System A9 | 1500 | | 13.64 | 178.8 | Superior | |

TABLE II

| | | | | Flow rate of purge | Pressure | |
|---|---|---|---|---|---|---|
| | | | | gas supplied to | stability | |
| | Cross-sectional | Length L | Ratio A/L | hollow interior 8 | in flow | |
| System | area A (mm²) | (mm) | (mm) | (SLM) | channel 5 | Remarks |
| System B1 | 200 | 10 | 20.00 | 200 | Superior | Present |
| System B2 | | 20 | 10.00 | 131.1 | Superior | invention |
| System B3 | | 50 | 4.00 | 52.5 | Superior | examples |
| System B4 | | 100 | 2.00 | 26.2 | Superior | |
| System B5 | | 110 | 1.82 | 23.8 | Superior | |
| System B6 | | 150 | 1.33 | 17.5 | Superior | |
| System B7 | | 200 | 1.00 | 13.1 | Superior | |
| System B8 | | 300 | 0.67 | 8.7 | inferior | Comparison |
| | | | | | | examples |

Referring to Tables I and II, in the systems A4 to A9 and B1 to B7 in which a ratio A/L was 0.9 or more, pressure stability in the flow channel 5 was superior. The possible reason is that because at a ratio A/L of 0.9 or more, the area A of a cross section through the flow path 7 is great enough to allow the flow path 7 to make the gradient of pressure between the flow channels 4 and 5 smaller. On the other hand, in all the systems in which a ratio is A/L of 20 mm or less, the flow rate of the supplied purge gas was only 200 SLM. When the ratio A/L was made more than 20 mm, necessary flow rate of purge gas went over 200 SLM, and drastically increased. The possible reason is that at a ratio A/L of 20 mm or less, the area A of a cross section through the flow path 7 is small enough to produce sufficient flow resistance in the flow path 7.

These results demonstrate that bringing the ratio A/L to 0.9 or more stables the gas flow in the cavity 12 within the flow channel 5, preventing the variations of the pressure and flow velocity in the interior space 11 of the flow channel 4. The results also demonstrate that bringing the ratio A/L to 20 mm or less produces sufficient resistance in the flow path 7, effectively reducing gas leakage. In addition, it is proved that purge gas flow rate can be decreased to reduce the manufacturing cost.

The presently disclosed embodiments should in all respects be considered to be illustrative and not limiting. The scope of the present invention is set forth not by the embodiments but by the scope of the patent claims, and is intended to include meanings equivalent to the scope of the patent claims and all modifications within the scope.

The vapor-phase growth system and vapor-phase growth method of the present invention was suitable for the deposition of III-V nitride semiconductor layers.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

What is claimed is:

1. A vapor-phase growth system, comprising:
a first gas supply duct;
a second gas supply duct linked to a downstream end of the first gas supply duct; and
a substrate support pedestal for supporting a substrate so that one of the substrate principal faces is exposed to the first gas-supply duct interior; wherein
a flow path is constituted by a clearance between the outer peripheral surface of the first gas supply duct and the inner peripheral surface of the second gas supply duct, the flow path leading from inside the first gas supply duct to outside the first gas supply duct, and the flow path width being from greater than 3 mm to 10 mm or less.

2. A vapor-phase growth system, comprising:
a first gas supply duct;
a second gas supply duct linked to a downstream end of the first gas supply duct; and
a substrate support pedestal for supporting a substrate so that one of the substrate principal faces is exposed to the first gas-supply duct interior; wherein
a flow path is formed by a clearance between the outer peripheral surface of the first gas supply duct and the inner peripheral surface of the second gas supply duct, the flow path leading from inside the first gas supply duct to outside the first gas supply duct, and a ratio A/L of the cross-sectional area A mm² of the flow path to the flow path length L mm being between 0.9 mm and 20 mm inclusive.

3. A vapor-phase growth system as set forth in claim 1, further comprising a chamber for housing the first and second gas supply ducts, substrate support pedestal, and flow path, wherein the chamber has a supply port for supplying gas to that portion of the chamber interior which is exterior to the first gas supply duct.

4. A vapor-phase growth system as set forth in claim 2, further comprising a chamber for housing the first and second gas supply ducts, substrate support pedestal, and flow path, wherein the chamber has a supply port for supplying gas to that portion of the chamber interior which is exterior to the first gas supply duct.

5. A vapor-phase growth system as set forth in claim 1, further comprising a differential-pressure meter for measuring difference between the pressure inside the first gas supply duct and the pressure in that portion of the chamber interior which is exterior to the first gas supply duct.

6. A vapor-phase growth system as set forth in claim 2, further comprising a differential-pressure meter for measuring difference between the pressure inside the first gas supply duct and the pressure in that portion of the chamber interior which is exterior to the first gas supply duct.

7. A vapor-phase growth method in which gas is supplied, via a gas supply duct provided within a chamber, over a substrate to carry out film deposition thereon, the method comprising:
a step of measuring difference between the pressure inside the gas supply duct and the pressure in that portion of the chamber interior which is exterior to the first gas supply duct; and
a step of supplying gas to that portion of the chamber interior which is exterior to the first gas supply duct so as to reduce the pressure difference measured in said measuring step.
